(19) United States
(12) Patent Application Publication
(10) Pub. No.: US 2025/0133943 A1
(43) Pub. Date: Apr. 24, 2025

(54) LIGHT PATH CONTROL MEMBER AND DISPLAY DEVICE COMPRISING SAME

(71) Applicant: LG INNOTEK CO., LTD., Seoul (KR)

(72) Inventors: In Hae LEE, Seoul (KR); Seung Jin KIM, Seoul (KR); Byung Sook KIM, Seoul (KR)

(21) Appl. No.: 18/730,525

(22) PCT Filed: Jan. 11, 2023
(86) PCT No.: PCT/KR2023/000518

§ 371 Date: Jul. 19, 2024

(30) Foreign Application Priority Data
Jan. 19, 2022 (KR) 10-2022-0008103

(51) Int. Cl. H10K 59/80; G02F 1/1335; G02F 1/1343; H10K 102/10

(52) U.S. Cl. CPC H10K 59/8792; G02F 1/133512; G02F 1/13439; H10K 59/871; H10K 2102/102; H10K 2102/103

(57) ABSTRACT

A light path control member according to an embodiment includes a first substrate; a first electrode disposed on the first substrate; a second substrate disposed on the first substrate; a second electrode disposed under the second substrate; and a light conversion part disposed between the first electrode and the second electrode and including a receiving part for receiving a light conversion material, and wherein the first electrode and the second electrode include different materials.

### TECHNICAL FIELD

An embodiment relates to a light path control member and a display device including the same.

### BACKGROUND ART

A light blocking film is a film that blocks light from being transmitted from a light source. The light blocking film is attached to a front of a display panel, which is a display device used for a mobile phone, laptop, tablet PC, vehicle navigation, or vehicle touch screen. The light blocking film adjusts a viewing angle of light according to an angle of incidence of light when the display outputs a screen. As a result, the user can view clear image quality at the desired viewing angle.

In addition, light blocking film is used for windows in vehicles or buildings. In detail, the light blocking film can prevent glare by partially shielding external light. Alternatively, the light blocking film can make an inside invisible from an outside.

That is, the light blocking film controls a movement path of light. As a result, the light blocking film can block light at an angle within a set range and transmit light at an angle within a set range. Accordingly, a transmission angle of light is controlled by the light blocking film.

The light blocking film can be divided into a light blocking film that can always control the viewing angle regardless of the surrounding environment, and a switchable light blocking film that allows the user to turn the viewing angle control on and off depending on the surrounding environment.

The switchable light blocking film includes a light conversion part including a receiving part. The receiving part is filled with a light conversion material including particles and a dispersion liquid. The particles can move by application of voltage. The receiving part may be converted into a light transmitting part and a light blocking part by dispersion and aggregation of the particles.

For example, a negative voltage is applied to one electrode and a positive voltage is applied to the other electrode. Accordingly, the negatively charged particles move in a direction of the electrode to which a positive voltage is applied.

When a negative voltage is applied to the electrode, positive ions can diffuse to a surface of the electrode. In addition, a yellowing phenomenon in which the color of the electrode is changed in response to the electrode may occur.

The yellowing phenomenon may be visually recognized as a stain from an outside. Thus, the user's visibility may be reduced.

Accordingly, a light path control member with a new structure that can solve the above problems is required.

### DISCLOSURE

### Technical Problem

An embodiment provides a light path control member with improved reliability and visibility.

### Technical Solution

A light path control member according to an embodiment includes a first substrate; a first electrode disposed on the first substrate; a second substrate disposed on the first substrate; a second electrode disposed under the second substrate; and a light conversion part disposed between the first electrode and the second electrode and including a receiving part for receiving a light conversion material, and wherein the first electrode and the second electrode include different materials.

### Advantageous Effects

In the light path control member according to the embodiment, the first electrode and the second electrode have different characteristics.

In detail, the first electrode and the second electrode have different materials, transparency, oxidation degree, thickness, surface roughness, resistance, or conductivity.

The first electrode and the second electrode may include appropriate materials depending on an applied voltage. Accordingly, yellowing of the first electrode and the second electrode can be prevented. Additionally, it is possible to prevent the transmittance of the first electrode and the second electrode from being reduced.

Accordingly, the light path control member according to the embodiment can have improved reliability and visibility.

### DESCRIPTION OF DRAWINGS

FIG. 1 is a view showing a perspective view of a light path control member according to an embodiment.

FIGS. 2 and 3 are cross-sectional views taken along the A-A′ region of FIG. 1.

FIGS. 4 and 5 are cross-sectional views of a display device to which a light path control member according to an embodiment is applied.

FIGS. 6 to 8 are views for explaining an embodiment of a display device to which an light path control member according to an embodiment is applied.

### BEST MODE

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, a light path control member according to an embodiment will be described with reference to the drawings. The light path control member described hereinafter may be a switchable light blocking film that is driven in a share mode or a light blocking mode according to an application of power.

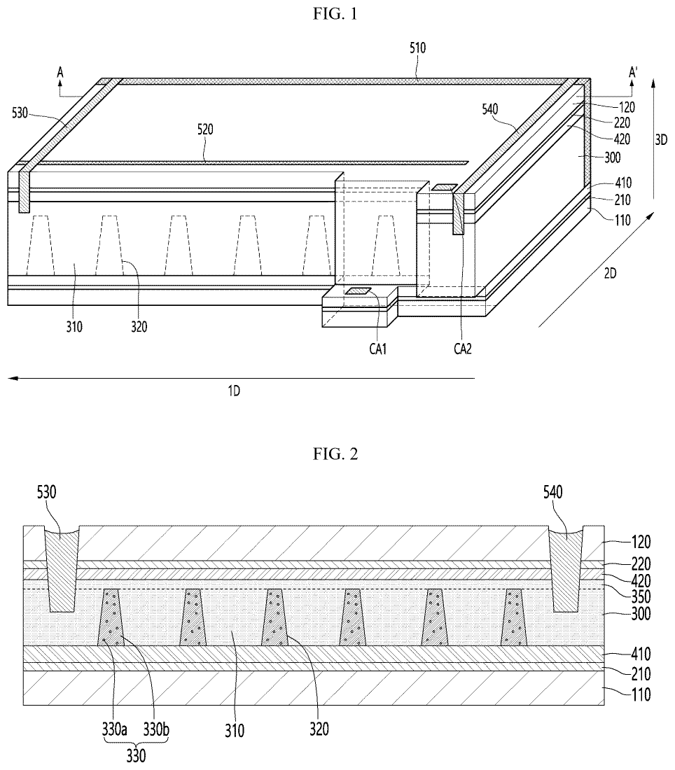

FIG. 1 is a perspective view of a light path control member according to an embodiment.

Referring to FIG. 1, the light path control member 1000 according to an embodiment includes a first substrate 110, a second substrate 120, a first electrode 210, a second electrode 220, and a light conversion part 300.

The first substrate 110 supports a first electrode 210. The first substrate 110 may be rigid or flexible.

The first substrate 110 may be transparent. For example, the first substrate 110 may include a transparent substrate capable of transmitting light.

The first substrate 110 may include glass, plastic, or a flexible polymer film. For example, the flexible polymer film may include any one of polyethylene terephthalate (PET), polycarbonate

(PC), acrylonitrile-butadiene-styrene copolymer (ABS), polymethyl methacrylate (PMMA), polyethylene naphthalate (PEN), polyether sulfone (PES), cyclic olefin copolymer (COC), Triacetylcellulose(TAC), polyvinyl alcohol (PVA) film, polyimide (PI), or polystyrene (PS).

The first substrate 110 may be a flexible substrate with flexible characteristics.

Also, the first substrate 110 may be curved or bent. Therefore, the light path control member may also have flexible, curved, or bent characteristics. Accordingly, the light path control member may be changed in various designs.

The first substrate 110 may extend in a first direction 1D, a second direction 2D, and a third direction 3D.

Specifically, the first direction 1D and the second direction 2D may correspond to a longitudinal direction or a width direction of the light path control member. In addition, the first direction 1D and the second direction 2D may be different directions. Also, the third direction 3D may correspond to a thickness direction of the light path control member.

Hereinafter, for convenience of explanation, the first direction 1D is defined in the longitudinal direction of the light path control member. Furthermore, the second direction 2D is defined in the width direction of the light path control member. Furthermore, the third direction 3D is defined in the thickness direction of the light path control member.

The first substrate 110 may have a thickness within a set range. For example, the first substrate 110 may have a thickness of 25 μm to 150 μm.

The first electrode 210 is disposed on one surface of the first substrate 110. In detail, the first electrode 210 is disposed on an upper surface of the first substrate 110. That is, the first electrode 210 is disposed between the first substrate 110 and the second substrate 120.

The first electrode 210 may include a conductive material. The first electrode 210 may be defined as an electrode to which a negative voltage is applied when the light path control member is driven in a share mode.

The first electrode 210 may have characteristics different from those of the second electrode 220 described below.

The second substrate 120 is disposed on the first substrate 110. Specifically, the second substrate 120 is disposed on the first electrode 210.

The second substrate 120 may include the same material as the first substrate 110.

Also, the thickness of the second substrate 120 may be the same as or similar to the thickness of the first substrate 110. For example, the thickness of the second substrate 120 may be 25 μm to 150 μm.

Also, the second substrate 120 may extend in the first direction 1D, the second direction 2D, and the third direction 3D corresponding to the first substrate 110.

A first connection region CA1 is disposed on the first substrate 110. A second connection region CA2 is disposed on the second substrate 120.

Conductive materials may be exposed on an upper surface of the first connection region CA1 and an upper surface of the second connection region CA2, respectively. For example, the first electrode 210 may be exposed in the first connection region CA1. Also, a conductive material may be exposed in the second connection region CA2. For example, a cutting region for filling the conductive material may be formed in the second substrate 120. Also, the conductive material may be filled in the cutting region. Accordingly, the second connection region may be formed.

The light path control member may be electrically connected to an external (flexible) printed circuit board by the first connection region CA1 and the second connection region.

The second electrode 220 is disposed on one surface of the second substrate 120. Specifically, the second electrode 220 is disposed on a lower surface of the second substrate 120. That is, the second electrode 220 is disposed between the first electrode 210 and the second substrate 120.

The second electrode 220 may include a conductive material. The second electrode 220 may be defined as an electrode to which a positive voltage is applied when the light path control member is driven in a share mode.

The first electrode 210 and the second electrode 220 include a conductive material. Voltages are respectively applied to the first electrode 210 and the second electrode 220. Also, negative ions or positive ions may be generated in each electrode due to a polarity of the applied voltage.

In this case, the ions may react with an electrode. A color of the electrode may be changed by the reaction. That is, a yellowing phenomenon of the electrode may occur.

Hereinafter, a light path control member capable of preventing the yellowing phenomenon of an electrode as described above will be described.

Voltages having different polarities are applied to the first electrode 210 and the second electrode 220. Accordingly, the light conversion particle 330a is moved in one direction.

For example, a negative voltage is applied to the first electrode 210. Accordingly, the first electrode 210 may be a negative electrode. Furthermore, a positive voltage is applied to the second electrode 220. Accordingly, the second electrode 220 may be a positive electrode.

The first electrode 210 and the second electrode 220 are disposed to face each other. Specifically, the first electrode 210 is disposed to face a lower surface of the receiving part 320. Also, the second electrode 220 is disposed to face an upper surface of the receiving part 310.

That is, the receiving part 320 is formed in a shape in which the width is narrowed while extending in one direction. In addition, the first electrode 210 is disposed to face the lower surface of the receiving part 320 having a wide width. In addition, the second electrode 220 is disposed to face the upper surface of the receiving part 310 having a narrow width.

The first electrode 210 and the second electrode 220 may include different materials.

The first electrode 210 may include a metal. Specifically, the first electrode 210 may include at least one metal selected chromium (Cr), nickel (Ni), copper (Cu), aluminum (Al), silver (Ag), molybdenum (Mo), Gold (Au), titanium (Ti), and alloys thereof.

In addition, the first electrode 210 may include a metal nanowire or a mesh electrode for light transmittance and low resistance.

For example, the first electrode 210 may include a plurality of metal nanowires. An overcoating layer may be disposed on the metal nanowire. Accordingly, a nanowire electrode may be formed.

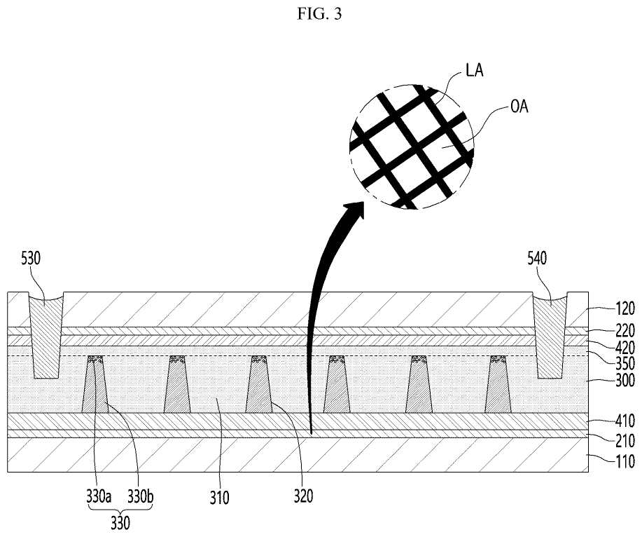

Alternatively, referring to FIG. 3, the first electrode 210 may include a plurality of conductive patterns. Specifically, the first electrode 210 may include a plurality of mesh lines LA crossing each other and a plurality of mesh openings OA formed by the mesh lines LA.

Accordingly, even though the first electrode 210 includes a metal, the first electrode is not visually recognized from the outside. Thus, visibility may be improved. Also, light transmittance is increased by the openings. Thus, luminance of the light path control member according to an embodiment may be improved.

Also, the second electrode 220 may include a transparent conductive material. For example, the second electrode 220 may include a conductive material having a light transmittance of 80% or more. For example, the second electrode 220 may include at least one metal oxide among indium tin oxide, indium zinc oxide, copper oxide, tin oxide, zinc oxide, and titanium oxide.

The first electrode 210 and the second electrode 220 include materials different from each other. Therefore, yellowing of the first electrode 210 and the second electrode 220 may be prevented.

Specifically, the first electrode 210 to which a negative voltage is applied includes a metal material. Also, the second electrode 220 to which a positive voltage is applied includes a transparent metal oxide. Accordingly, yellowing of the first electrode 210 and the second electrode 220 may be prevented.

For example, the first electrode 210 to which the negative voltage is applied may include a metal oxide such as indium tin oxide. In this case, the cation generated by the negative voltage moves to the surface of the first electrode 210 and contacts each other. Also, tin (Sn²⁺) in a divalent oxidation state present in the first electrode 210 meets the cation. Therefore, it may be changed into tin (Sn⁴⁺) in a tetravalent oxidation state by a reaction such as the following formula.

X⁺Sn²⁺=2X⁰+Sn⁴⁺ [Chemical formula]

Accordingly, an oxidation number of tin is increased at the surface of the first electrode 210. Accordingly, a color of the first electrode 210 is changed. Accordingly, yellowing may be generated in the first electrode 210.

Accordingly, the light path control member according to an embodiment forms the first electrode 210 with metal. Accordingly, yellowing of the electrode due to the reaction may be prevented.

Also, the second electrode 220 to which a positive voltage is applied may include a metal. In this case, cations are generated by ionization of a metal generated according to the application of a positive voltage. For example, the second electrode 220 may include a silver (Ag) nanowire or a silver (Ag) mesh electrode. In this case, when a positive voltage is applied to the second electrode 220, the second electrode 220 may be ionized into Ag⁺ ions.

In this case, the ionized Ag⁺ ions move to the first electrode 210 of the negative electrode, which is the opposite electrode. Subsequently, electrons may be received again to be generated as colloids. Accordingly, a state of the second electrode 210 is different from an initial state. Also, a structure of the nanowire for securing transmissivity may be changed. Accordingly, the light transmittance of the second electrode 220 may be reduced.

Furthermore, the cation generated from the second electrode 220 moves to the surface of the first electrode 210 and contacts the surface thereof. Furthermore, tin (Sn²⁺) in a divalent oxidation state present in the first electrode 210 meets a cation, and therefore, it may be changed into tin (Sn⁴⁺) in a tetravalent oxidation state by a reaction described in the above Chemical Formula.

That is, the yellowing phenomenon of the first electrode 210 may be accelerated by the cations generated from the second electrode 220.

Accordingly, the light path control member according to an embodiment forms the second electrode 220 with transparent metal oxide. Accordingly, a decrease in light transmittance and yellowing of the electrode due to the reaction may be prevented.

The first electrode 210 and the second electrode 220 may have different transparency from each other.

The transparency of the first electrode 210 may be less than that of the second electrode 220. Specifically, the second electrode 220 may be more transparent than the first electrode 210.

That is, the transparency of the second electrode 220 including the transparent metal may be greater than that of the first electrode 220 including the metal nanowire or the metal mesh electrode.

The transparency of the second electrode 220 closer to the user's field of view is greater than that of the first electrode 210. Accordingly, it is difficult for the user to recognize the decrease in transparency of the light path control member from the outside. Accordingly, the user's visibility may be improved.

The first electrode 210 and the second electrode 220 may have different oxidation degrees.

The oxidation degree of the first electrode 210 may be less than that of the second electrode 220. Specifically, the second electrode 220 may include oxide. In addition, the first electrode 210 may include non-oxide.

That is, the oxidation degree of the second electrode 220 including the transparent metal oxide may be greater than that of the first electrode 220 including the metal nanowire or the metal mesh electrode.

Accordingly, the second electrode disposed close to the outside of the light path control member has a high oxidation degree. Accordingly, corrosion of the electrode caused by penetration of moisture from the outside can be reduced.

The first electrode 210 and the second electrode 220 may have different thicknesses. Specifically, the thickness of the first electrode 210 may be greater than the thickness of the second electrode 220.

Also, a thickness T1 of the first electrode 210 may be in a range of 50 nm to 3 μm. When the thickness T1 of the first electrode 210 is less than 50 nm, process efficiency may be reduced. Also, when the thickness T1 of the first electrode 210 is more than 3 μm, the thickness of the light path control member may be increased.

Also, a thickness T2 of the second electrode 220 may be in a range of 0.1 μm to 0.5 μm. When the thickness T2 of the second electrode 220 is less than 0.1 μm, process efficiency may be reduced. Also, the sheet resistance of the second electrode 220 may be increased. Also, when the thickness of the second electrode 220 is more than 0.5 μm, the thickness of the light path control member may be increased.

A thickness T1 of the first electrode 210 may be greater than a thickness T2 of the second electrode 220 within the range.

Also, the first electrode 210 and the second electrode 220 may have different magnitudes of resistance.

The resistance of the second electrode 220 may be greater than the resistance of the first electrode 210. Specifically, the sheet resistance of the second electrode 220 may be greater than the sheet resistance of the first electrode 210.

For example, the sheet resistance of the second electrode 220 may be 50 Ω/□ to 2000 Ω/□. Also, the sheet resistance of the first electrode 210 may be 0.1 Ω/□ to 50 Ω/□.

Also, the first electrode 210 and the second electrode 220 may have different conductivity from each other.

Specifically, the conductivity of the first electrode 210 may be greater than that of the second electrode 220.

Since the conductivity of the first electrode 210 is greater than that of the second electrode 220, the electrical connection characteristics between the light path control member and the external printed circuit board may be improved.

The first electrode 210 and the second electrode 220 may have surface roughness.

Specifically, the surface roughness of the first electrode 210 may be greater than that of the second electrode 220.

Since the surface roughness of the first electrode 210 is greater than that of the second electrode 220, reliability of the light path control member may be improved.

That is, the light conversion part 300 and the first electrode 210 may be adhered to each other by the adhesive layer 410. Since the surface roughness of the first electrode 210 contacting the adhesive layer 410 increases, a contact area between the first electrode 210 and the adhesive layer 410 may increase.

Therefore, since the contact area between the first electrode 210 and the adhesive layer 410 is increased, the adhesion characteristics between the first electrode 210 and the adhesive layer 410, which are different materials, may be improved.

The first electrode 210 and the second electrode 220 may have different areas per unit area.

Specifically, an area per unit area of the first electrode 210 may be smaller than an area per unit area of the second electrode 220.

Since the second electrode 220 includes a transparent material, the second electrode 220 may be disposed as a surface electrode on the second substrate 120.

On the other hand, since the first electrode 210 includes an opaque metal material, it may be disposed as a mesh-shaped pattern electrode or a nanowire on the first substrate 110.

Accordingly, the area per unit area of the first electrode 210 may be smaller than the area per unit area of the second electrode 220.

Since the first electrode 210 has higher conductivity than the second electrode 220, even when an area per unit area is small, the first electrode 210 may have sufficient conductivity. Accordingly, the transmittance of light incident toward the first substrate 110 may be increased. Accordingly, the luminance of the light path control member may be improved.

In the light path control member according to the embodiment, the first electrode and the second electrode have different characteristics.

Specifically, the first electrode and the second electrode have different materials, transparency, oxidation, thickness, surface roughness, resistance, or conductivity.

In particular, the first electrode and the second electrode include an appropriate material according to the type of voltage applied thereto.

Therefore, yellowing of the first electrode and the second electrode may be prevented. Also, it is possible to prevent a decrease in transmittance of the first electrode and the second electrode.

Accordingly, the light path control member according to an embodiment may have improved reliability and visibility.

The light conversion part 300 may be disposed between the first substrate 110 and the second substrate 120. Specifically, the light conversion part 300 may be disposed between the first electrode 210 and the second electrode 220.

An adhesive layer 410 may be disposed between the first electrode 210 and the light conversion part 300. Accordingly, the first substrate 110 and the light conversion part 300 may be adhered to each other.

The adhesive layer 410 may have a thickness within a set range. For example, the adhesive layer 410 may have a thickness of 10 μm to 30 μm.

Also, a buffer layer 420 may be disposed between the second electrode 220 and the light conversion part 300. Accordingly, adhesion between the second electrode 220 including different materials and the light conversion part 300 may be improved.

The buffer layer 420 may have a thickness within a set range. For example, the thickness of the buffer layer 420 may be less than 1 μm.

The light conversion part 300 may include a plurality of partition wall parts 310 and an receiving part 320. A light conversion material 330 including light conversion particles that move according to the application of a voltage and a dispersion for dispersing the light conversion particles may be disposed in the receiving part 320. Light transmission characteristics of the light path control member may be changed by the light conversion particles.

FIGS. 2 and 3 are views illustrating a cross-sectional view taken along line A-A′ of FIG. 1.

Referring to FIGS. 2 and 3, the light conversion part 300 may include a partition wall part 310 and an receiving part 320.

The partition wall part 310 may be defined as a partition wall area that divides a plurality of receiving parts. The partition wall part 310 may transmit light. That is, light emitted from the first substrate 110 or the second substrate 120 may transmit the partition wall part.

The partition wall part 310 and the receiving part 320 may have different widths. For example, the width of the partition wall part 310 may be greater than the width of the receiving part 320.

In addition, the width of the receiving part 320 may be narrowed while extending from the first electrode 210 toward the second electrode 220.

The partition wall part 310 and the receiving part 320 may be alternately disposed. For example, each partition wall part 310 is disposed between adjacent receiving parts 320. Also, each receiving part 320 is disposed between adjacent partition wall parts 310.

The partition wall part 310 may include a transparent material. The partition wall part 310 may include a material capable of transmitting light.

The partition wall part 310 may include a resin material. For example, the partition wall part 310 may include a photocurable resin material. For example, the partition wall part 310 may include a UV resin or a transparent photoresist resin. Alternatively, the partition wall part 310 may include a urethane resin or an acrylic resin.

The receiving part 320 may be formed by partially passing through the light conversion part 300. Accordingly, the receiving part 320 is disposed in contact with the adhesive layer 410. Also, the receiving part 3200 is disposed to be spaced apart from the buffer layer 420. Accordingly, a base part 350 may be formed between the receiving part 320 and the buffer layer 420.

The receiving part 320 may be tilted in one direction. Accordingly, the moiré phenomenon may be prevented. Therefore, the user's visibility may be improved.

The light conversion material 330 may be sealed inside the receiving part by sealing parts 510, 520, 530, and 540.

A light conversion material 330 including light conversion particles 330a and dispersion 330b may be disposed in the receiving part 320.

The dispersion 330b disperses the light conversion particles 330a. The dispersion 330b may include a transparent material. The dispersion 330b may include a non-polar solvent. Also, the dispersion 330b may include a material capable of transmitting light. For example, the dispersion 330b may include at least one material among halocarbon-based oil, paraffin-based oil, and isopropyl alcohol.

The light conversion particles 330a are dispersed in the dispersion 330b.

The light conversion particle 330a may include a material capable of absorbing light. That is, the light conversion particle 330a may be a light absorbing particle, and the light conversion particle 330a may have a color. For example, the light conversion particle 330a may have a black-based color. For example, the light conversion particle 330a may include carbon black particles.

A surface of the light conversion particle 330a may be charged and have a polarity. For example, a surface of the light conversion particle 330a may be charged with a negative charge. Accordingly, the light conversion particle 330a may be moved toward the second electrode 220 by applying a voltage.

The light transmittance of the receiving part 320 may be changed by the light conversion particle 330a. Specifically, the receiving part 320 may be changed into a light blocking part and a light transmitting part. That is, the receiving part 330a may change the light transmittance by dispersion and aggregation of the light conversion particles 330a.

For example, the light path member according to an embodiment may be switched from a first mode to a second mode by a voltage applied to the first electrode 210 and the second electrode 220. Alternatively, the light path member may be switched from the second mode to the first mode.

Specifically, in the first mode, the receiving part 320 serves as a light blocking part. Accordingly, light having a set range angle may be blocked by the receiving part 320. Accordingly, a viewing angle of the user may be narrowed. Accordingly, the light path control member may be driven in a privacy mode.

Also, in the second mode, the receiving part 320 becomes a light transmitting part. Accordingly, light may be transmitted from both the partition wall part 310 and the receiving part 320. Accordingly, the viewing angle of the user may be widened. Accordingly, the light path control member may be driven in a share mode.

The switching from the first mode to the second mode may be implemented by the movement of the light conversion particle 330a. The light conversion particle 330a has electric charges on the surface thereof. The light conversion particle 330a may be moved toward a first electrode or a second electrode when a voltage is applied due to the characteristics of the surface charge.

For example, when a voltage is not applied to the light path control member, the light conversion particles 330a are uniformly dispersed in the dispersion 330b. Accordingly, light of the receiving part 320 may be blocked by the light conversion particles 330a. Accordingly, in the first mode, the receiving part 320 may be driven as the light blocking part.

In addition, when a voltage is applied to the light path control member, the light conversion particles 330a may be moved. For example, the light conversion particles 330a may be moved in a direction of one end or the other end of the receiving part 320 by the voltage. That is, the light conversion particles 330a may be moved in a direction of the first electrode 210 or the second electrode 220.

For example, when a voltage is applied to the first electrode 210 and/or the second electrode 220, an electric field is formed between the first electrode 210 and the second electrode 220. Accordingly, the light conversion particles 330a of which the surface is negatively charged may be moved in a direction of an electrode having a positive electrode among the first electrode 210 and the second electrode 220 using the dispersion 330b as a medium.

Referring to FIG. 2, when a voltage is not applied to the first electrode 210 and/or the second electrode 220, the light conversion particles 330a may be uniformly dispersed in the dispersion 330b. Accordingly, the receiving part 320 may be driven by the light blocking part.

Referring to FIG. 3, when a voltage is applied to the first electrode 210 and/or the second electrode 220, the light conversion particle 330a may move in the direction of the second electrode 220. That is, the light conversion particle 330a moves in the one direction. Accordingly, the receiving part 320 may be driven by the light transmitting part.

Accordingly, the light path control member according to the embodiment may be driven in two modes according to the user's surrounding environment or the like. That is, if the user wants to transmit light only at an angle within a set range, the receiving part may be driven as the light blocking part. Alternatively, in an environment in which the user requires a wide viewing angle and high luminance, the receiving part may be driven by a light transmitting part.

Therefore, since the light path control member according to the embodiment may be implemented in two modes according to the user's request, the light path member may be applied regardless of the user's environment.

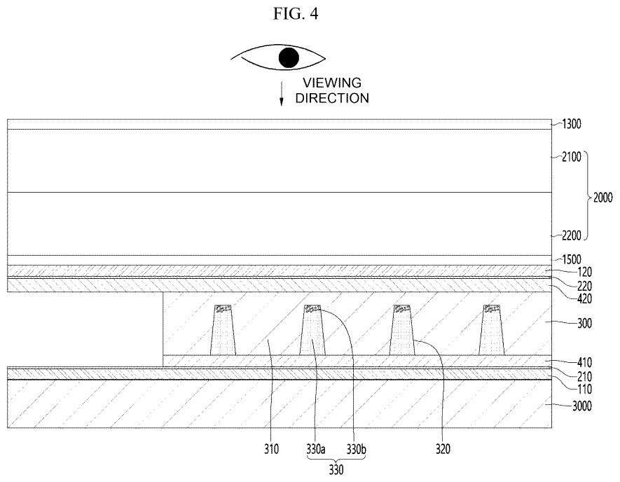

Hereinafter, a display device and a display device to which a light path control member according to an embodiment is applied will be described with reference to FIGS. 4 to 8.

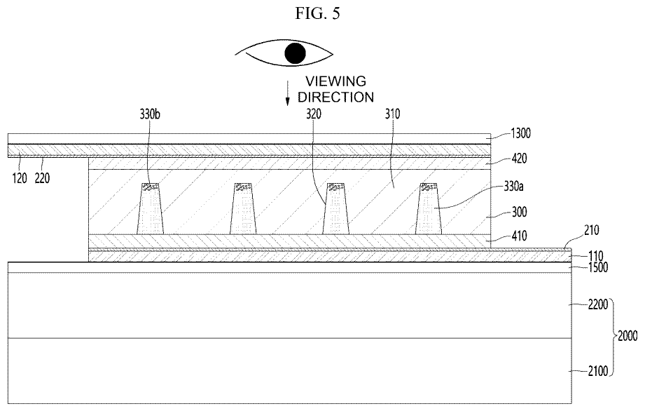

Referring to FIGS. 4 and 5, the light path control member 1000 according to the embodiment may be disposed on or below the display panel 2000.

The display panel 2000 and the light path control member 1000 may be disposed to be adhered to each other. For example, the display panel 2000 and the light path control member 1000 may be adhered to each other via an adhesive member 1500. The adhesive member 1500 may be transparent. For example, the adhesive member 1500 may include an adhesive or an adhesive layer including a light transparent adhesive material.

The adhesive member 1500 may include a release film. In detail, when adhering the light path control member and the display panel, the light path control member and the display panel may be adhered after the release film is removed.

The display panel 2000 may include a first base substrate 2100 and a second base substrate 2200. When the display panel 2000 is a liquid crystal display panel, the light path control member may be formed under the liquid crystal panel. That is, when a surface viewed by the user in the liquid crystal panel is defined as an upper portion of the liquid crystal panel, the light path control member may be disposed under the liquid crystal panel. The display panel 2000 may be formed in a structure in which the first base substrate 2100 including a thin film transistor (TFT) and a pixel electrode and the second base substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first base substrate 2100 and the second base substrate 2200 is bonded to the first base substrate 2100 with the liquid crystal layer interposed therebetween. That is, a thin film transistor may be formed on the first base substrate 2100, a protective film may be formed on the thin film transistor, and a color filter layer may be formed on the protective film. In addition, a pixel electrode in contact with the thin film transistor may be formed on the first base substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 4, the light path control member may be disposed under the liquid crystal panel and on the backlight unit 3000, and the light path control member may be disposed between the backlight unit 3000 and the display panel 2000.

Alternatively, as shown in FIG. 5, when the display panel 2000 is an organic light emitting diode panel, the light path control member may be formed on the organic light emitting diode panel. That is, when the surface viewed by the user in the organic light emitting diode panel is defined as an upper portion of the organic light emitting diode panel, the light path control member may be disposed on the organic light emitting diode panel. The display panel 2000 may include a self-luminous element that does not require a separate light source. In the display panel 2000, a thin film transistor may be formed on the first base substrate 2100, and an organic light emitting element in contact with the thin film transistor may be formed. The organic light emitting element may include an anode, a cathode, and an organic light emitting layer formed between the anode and the cathode. In addition, the second base substrate 2200 configured to function as an encapsulation substrate for encapsulation may be further included on the organic light emitting element.

In addition, although not shown in drawings, a polarizing plate may be further disposed between the light path control member 1000 and the display panel 2000. The polarizing plate may be a linear polarizing plate or an external light reflection preventive polarizing plate. For example, when the display panel 2000 is a liquid crystal display panel, the polarizing plate may be a linear polarizing plate. Further, when the display panel 2000 is the organic light emitting diode panel, the polarizing plate may be an external light reflection preventing polarizing plate.

In addition, an additional functional layer 1300 such as an anti-reflection layer, an anti-glare, or the like may be further disposed on the light path control member 1000. Specifically, the functional layer 1300 may be adhered to one surface of the first substrate 110 of the light path control member. Although not shown in drawings, the functional layer 1300 may be adhered to the first substrate 110 of the light path control member via an adhesive layer. In addition, a release film for protecting the functional layer may be further disposed on the functional layer 1300.

Further, a touch panel may be further disposed between the display panel and the light path control member.

It is shown in the drawings that the light path control member is disposed at an upper portion of the display panel, but the embodiment is not limited thereto, and the light path control member may be disposed at various positions such as a position in which light is adjustable, that is, a lower portion of the display panel, or between a second substrate and a first substrate of the display panel, or the like.

In addition, it is shown in the drawings that the light conversion part of the light path control member according to the embodiment is in a direction parallel or perpendicular to an outer surface of the second substrate, but the light conversion part is formed to be inclined at a predetermined angle from the outer surface of the second substrate. Through this, a moiré phenomenon occurring between the display panel and the light path control member may be reduced.

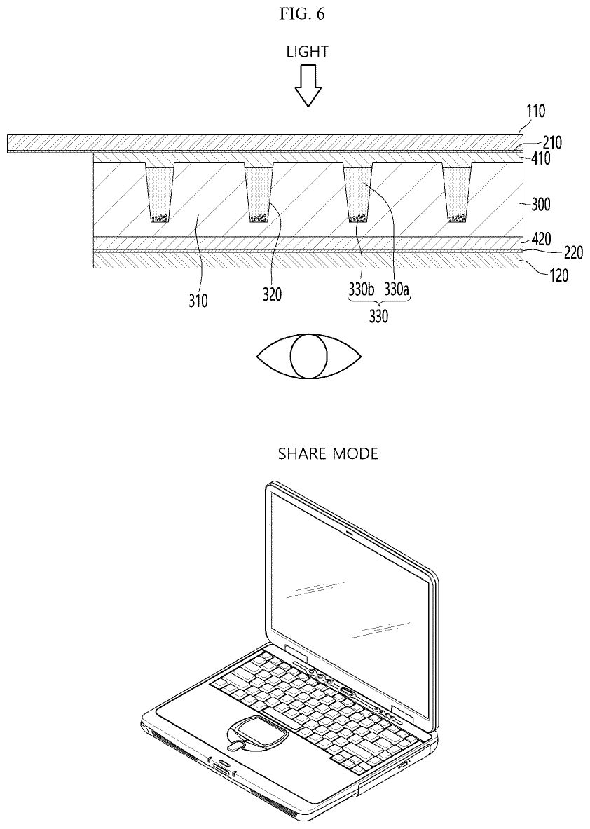

Referring to FIGS. 6 to 8, the light path control member according to the embodiment may be applied to a display device that displays a display.

Referring to FIGS. 6 to 8, the light path control member according to an embodiment may be applied to a display device that displays a display.

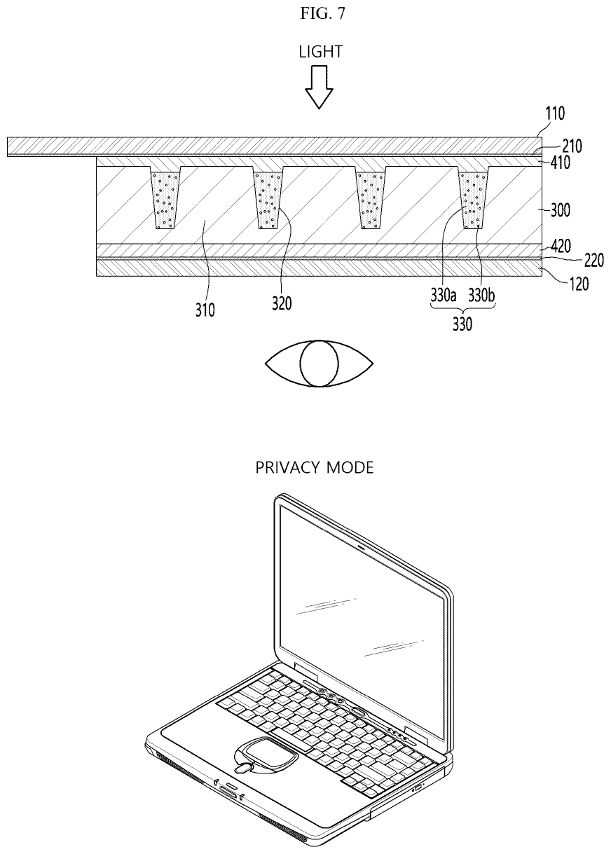

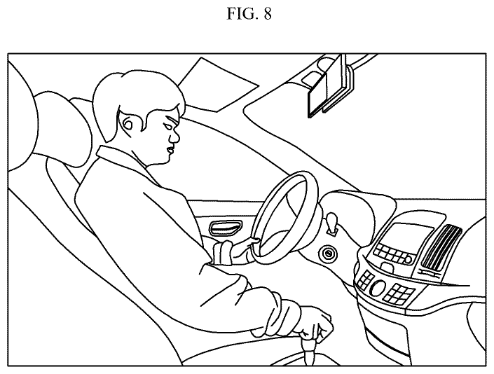

For example, when power is applied to the light path control member as shown in FIG. 6, the receiving part functions as the light transmitting part, so that the display device may be driven in the public mode, and when power is not applied to the light path control member as shown in FIG. 7, the receiving part functions as the light blocking part, so that the display device may be driven in the light blocking mode.

Accordingly, a user may easily drive the display device in a privacy mode or a normal mode according to application of power.

Light emitted from the backlight part or the self-luminous element may move from the first substrate toward the second substrate. Alternatively, the light emitted from the backlight part or the self-luminous element may also move from the second substrate toward the first substrate.

In addition, referring to FIG. 8, the display device to which the light path control member according to the embodiment is applied may also be applied inside a vehicle.

For example, the display device including the light path control member according to the embodiment may display a video confirming information of the vehicle and a movement route of the vehicle. The display device may be disposed between a driver seat and a passenger seat of the vehicle.

In addition, the light path control member according to the embodiment may be applied to a dashboard that displays a speed, an engine, an alarm signal, and the like of the vehicle.

Further, the light path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. A light path control member comprising:
a first substrate;
a first electrode disposed on the first substrate;
a second substrate disposed on the first substrate;
a second electrode disposed under the second substrate; and
a light conversion part disposed between the first electrode and the second electrode and including a receiving part for receiving a light conversion material, and
wherein the receiving part has a width of a first region adjacent to the first electrode in a horizontal direction greater than a width of a second region adjacent to the second electrode in a horizontal direction, and
wherein a transparency of the first electrode adjacent to the first region having the width greater than that of the second region is smaller than that of the second electrode adjacent to the second region having the width smaller than that of the first region.

2. The light path control member of claim 1, wherein the first electrode includes a metal nanowire or a mesh electrode including at least one metal among chromium (Cr), nickel (Ni), copper (Cu), aluminum (Al), silver (Ag), and molybdenum (Mo); and
wherein the second electrode includes indium tin oxide, indium zinc oxide, copper oxide, tin oxide, zinc oxide or titanium oxide.

3. The light path control member of claim 1, wherein the first electrode and the second electrode include different materials

4. The light path control member of claim 1, wherein an oxidation degree of the second electrode is greater than that of the first electrode.

5. The light path control member of claim 1, wherein a thickness of the first electrode is greater than that of the second electrode.

6. The light path control member of claim 1, wherein a resistance of the second electrode is greater than that of the first electrode.

7. The light path control member of claim 1, wherein a conductivity of the first electrode is greater than that of the second electrode.

8. The light path control member of claim 1, wherein a surface roughness of the first electrode is greater than that of the second electrode.

9. The light path control member of claim 1, wherein a negative voltage is applied to the first electrode,
wherein a positive voltage is applied to the second electrode, and
wherein light conversion particles of the light conversion material disposed inside the receiving part move in a direction of the first electrode.

10. The light path control member of claim 1, comprising:
a sealing part sealing the light conversion material,
wherein a lower end of the sealing part overlaps the receiving part along the horizontal direction.

11. The light path control member of claim 10, wherein the lower end of the sealing part is closer to the first region of the receiving part than to the second region of the receiving part.

12. The light path control member of claim 10, wherein the sealing part partially penetrates the light conversion part while entirely penetrating the second substrate and the second electrode.

13. The light path control member of claim 10, wherein the sealing part includes:
a first sealing part and a second sealing part extending in a first direction and facing in a second direction different from the first direction; and
a third sealing part and a fourth sealing part extending in the second direction and facing in the first direction.

14. The light path control member of claim 1, wherein an area per unit area of the first electrode is smaller than an area per unit area of the second electrode.

15. A display device comprising:
a panel including at least one of a display panel or a touch panel; and
a light path control member disposed on or under the panel,
wherein the light path control member includes:
a first substrate;
a first electrode disposed on the first substrate;
a second substrate disposed on the first substrate;
a second electrode disposed under the second substrate; and
a light conversion part disposed between the first electrode and the second electrode and including a receiving part for receiving a light conversion material,
wherein the receiving part has a width of a first region adjacent to the first electrode in a horizontal direction greater than a width of a second region adjacent to the second electrode in a horizontal direction, and
wherein a transparency of the first electrode adjacent to the first region having the width greater than that of the second region is smaller than that of the second electrode adjacent to the second region having the width smaller than that of the first region.

16. The display device of claim 1, wherein the panel includes a backlight unit and a liquid crystal display panel,
wherein the light path control member is disposed between the backlight unit and the liquid crystal display panel, and
wherein light emitted from the backlight unit moves from the first substrate toward the second substrate.

17. The display device of claim 15, wherein the panel includes an organic light emitting diode panel,
wherein the light path control member is disposed on the organic light emitting diode panel, and
wherein light emitted from the panel moves from the first substrate toward the second substrate.

18. The display device of claim 15, wherein an oxidation degree of the second electrode is greater than that of the first electrode,
wherein a thickness of the first electrode is greater than that of the second electrode,
wherein a resistance of the second electrode is greater than the resistance of the first electrode,
wherein a conductivity of the first electrode is greater than that of the second electrode, and
wherein a surface roughness of the first electrode is greater than that of the second electrode.

19. The display device of claim 15, wherein the light path control member includes a sealing part sealing the light conversion material,
wherein a lower end of the sealing part overlaps the receiving part along a horizontal direction, and
wherein a lower end of the sealing part is positioned closer to the first region of the receiving part than to the second region of the receiving part.
